(19) United States
(12) Patent Application Publication
(10) Pub. No.: US 2025/0254893 A1
(43) Pub. Date: Aug. 7, 2025

(54) PROCESSING CORE INCLUDING HIGH CAPACITY LOW LATENCY STORAGE MEMORY

(71) Applicant: Sandisk Technologies, Inc., Milpitas, CA (US)

(72) Inventors: Nagesh Vodrahalli, Los Altos, CA (US); Rama Shukla, Saratoga, CA (US); Alper Ilkbahar, San Jose, CA (US); Chih Yang Li, Menlo Park, CA (US); Shrikar Bhagath, San Jose, CA (US)

(73) Assignee: Sandisk Technologies, Inc., Milpitas, CA (US)

(21) Appl. No.: 18/933,962

(22) Filed: Oct. 31, 2024

Related U.S. Application Data
(60) Provisional application No. 63/551,026, filed on Feb. 7, 2024.

(51) Int. Cl. H10B 80/00; G11C 14/00; G11C 16/04; H01L 23/528; H01L 25/065

(52) U.S. Cl. CPC H10B 80/00; H01L 23/528; H01L 25/0657; G11C 14/0018; G11C 16/0483; H01L 2225/06541; H01L 2225/06548

(57) ABSTRACT

A non-volatile memory stack provides high bandwidth support to a specialized processor such as an AI processor. The high bandwidth flash (HBF) stack may be unitary, including all non-volatile memory together with a memory controller, or it may be hybrid, including a mixture of non-volatile and volatile memory together with a controller. The processor may be mounted on an interposer, and one or more of the HBF stacks and/or hybrid HBF stacks may then be mounted on the interposer alongside the processor.

### CLAIM OF PRIORITY

The present application claims priority from U.S. Provisional Patent Application No. 63/551,026, filed Feb. 7, 2024, which application is incorporated by reference herein in its entirety.

### BACKGROUND

Processing cores are used for performing calculations, executing instructions and managing components and peripherals to drive the operation of computers and other electronic devices. Typical processing cores include a processor such as a central processing unit that uses non-volatile and/or volatile memory to function. Non-volatile memories may for example comprise stacks of NAND semiconductor dies mounted on a substrate next to the processor or far away from the processor as may be. These semiconductor dies offer large memory capacities, but due in part to their being spaced away from the processor on the circuit board, offer relatively low bandwidth rates, high power requirements and unwanted parasitics. Volatile memories may for example comprise stacks of DRAM semiconductor dies that are specially designed to offer higher bandwidth and smaller power requirements, but at a cost of lower memory capacities in comparison to NAND dies. Traditional processing cores optimize the balance between speed and memory capacity. Typically, DRAM serves as the primary working memory, offering quick access to frequently used data. NAND memory is used for secondary storage, providing ample capacity for long-term data storage but at a slower access speed.

Recently, sophisticated specialized processing cores have been developed including high-speed artificial intelligence (AI) processing devices and graphics processing units (GPUs). AI processors are optimized for executing artificial neural networks, again using parallel processing that allows them to process a large volume of data simultaneously. GPUs are specialized processors designed to accelerate the rendering and manipulation of images, videos, and complex graphical computations, in part using a multitude of processors operating in parallel. This allows the GPUs to process a large volume of data simultaneously.

Specialized processing cores such as GPUs and AI processors have large memory capacity requirements that are not adequately serviced by conventional volatile memories. However, these devices also have high bandwidth and low power requirements that are not adequately serviced by conventional non-volatile memories.

Moreover, AI processors are implemented and used in two distinct phases—a training phase where the AI processor is trained for its purpose, and an inference phase, where the AI processor is deployed for query response. During the training phase, the AI processor performs a tremendous number of read/write operations on the memory. Such large number of write operations can degrade a traditional non-volatile memory.

### DESCRIPTION OF THE DRAWINGS

FIG. 1 is a flowchart for forming a processing core according to embodiments of the present technology.

FIG. 2 is a top view of a first semiconductor wafer, and a first semiconductor tile therefrom, according to embodiments of the present technology.

FIG. 3 is a top view of a second semiconductor wafer, and a second semiconductor tile therefrom, according to embodiments of the present technology.

FIG. 4 is a cross-sectional edge view of a first semiconductor tile according to embodiments of the present technology.

FIG. 5 is a cross-sectional edge view of a second semiconductor tile according to embodiments of the present technology.

FIG. 6 is a cross-sectional edge view of a CBA memory tile including a first semiconductor tile bonded to a second semiconductor tile according to embodiments of the present technology.

FIGS. 7-12 are cross-sectional edge views of a second semiconductor die according to an alternative embodiment of the present technology.

FIGS. 13-18 are views of a first semiconductor die according to an alternative embodiment of the present technology.

FIGS. 19-21 are perspective views showing various bump pad patterns on one of the first and second semiconductor tile according to embodiments of the present technology.

FIGS. 22 and 23 are edge and perspective views showing a CBA memory tile according to embodiments of the present technology.

FIG. 24 is a perspective view of a CBA memory tile mounted on an interposer according to embodiments of the present technology.

FIG. 25 is an exploded perspective view of one or more volatile memories being mounted on the CBA memory tile of FIG. 24 according to embodiments of the present technology.

FIG. 26 is a cross-sectional edge view of a volatile memory tile according to embodiments of the present technology.

FIG. 27 is a perspective view of an integrated processing core including a processor, a CBA memory tile and one or more volatile memories mounted on an interposer according to embodiments of the present technology.

FIG. 28 is a perspective view of a completed processing core including a processor, a CBA memory tile, one or more volatile memories and HBM stacks mounted on an interposer according to embodiments of the present technology.

FIG. 29 is a cross-sectional edge view of the completed processing core of FIG. 28 including a processor, a CBA memory tile, one or more volatile memories and HBM stacks mounted on an interposer according to embodiments of the present technology.

FIG. 30 is a perspective view of a completed processing core including a processor, a CBA memory tile and one or more volatile memories mounted on an interposer according to alternative embodiments of the present technology.

FIG. 31 is a cross-sectional edge view of the completed processing core of FIG. 30 including a processor, a CBA memory tile and one or more volatile memories mounted on an interposer according to alternative embodiments of the present technology.

FIG. 32 is a perspective view of a completed processing core including a processor, a CBA memory tile and one or more volatile memories according to alternative embodiments of the present technology.

FIG. 33 is a cross-sectional edge view of the completed processing core of FIG. 32 including a processor, a CBA memory tile and one or more volatile memories according to alternative embodiments of the present technology.

FIG. 34 is a functional block diagram of a CBA memory tile coupled to a processor according to embodiments of the present technology.

FIG. 35 is a perspective view of an HBF stack according to embodiments of the present technology.

FIG. 36 is a perspective view of a completed processing core including a processor and HBF and HBM stacks according to alternative embodiments of the present technology.

FIG. 37 is a cross-sectional edge view of the processing core of FIG. 36 according to embodiments of the present technology.

FIG. 38 is a perspective view of a completed processing core including a processor and hybrid HBF stacks according to alternative embodiments of the present technology.

FIGS. 39-40 are edge views of examples of hybrid HBF stacks according to different embodiments of the present technology.

### DETAILED DESCRIPTION

The present technology will now be described with reference to the figures, which in embodiments, relate to a processing core including a processor integrated with a high bandwidth low latency storage memory. The processor may for example be a large artificial intelligence (AI) processor, but it may other types of specialized processors including a graphics processing unit (GPU). The storage memory may include both non-volatile memory and volatile memory.

In a first inventive aspect, the storage memory may be fabricated as a CBA (CMOS bonded to array) memory including a NAND memory semiconductor die coupled to a second semiconductor die which may be a combination CMOS logic circuit and volatile memory die. In particular, especially for large NAND memory tiles, only a portion of the second semiconductor die is needed for the CMOS logic circuit. The remaining portions of the second semiconductor die may therefore be used for low latency volatile memory. In addition to providing high bandwidth access to memory, integrating volatile memory into the CBA memory reduces wear on the memory which may otherwise occur during the large number of write operations needed during training of the AI processor.

In a second inventive aspect, the cells of a NAND memory array (within a CBA memory or otherwise) are partitioned to store different numbers of bits. The cells of a NAND memory array may conventionally be partitioned to hold one bit of data (Single-Level Cells, or SLCs), two bits of data (Multi-Level Cells, or MLCs), three bits of data (Triple-Level Cells, or TLCs) or four bits of data (Quad-Level Cells, or QLCs). SLCs hold the least amount of data, but also exhibit the least amount of wear during write operations over their life-cycle. Conversely, QLCs hold the most amount of data, but exhibit the highest amount of wear over their life-cycle. In accordance with aspects of the present technology, a NAND memory array may be partitioned to include SLCs, and at least one other type of cell-MLCs, TLCs and/or QLCs. The SLCs may be used largely or exclusively during the write-intensive training of the AI processor to minimize wear on the memory during training. Thereafter, the other memory cells (MLCs, TLCs and/or QLCs) may be used largely or exclusively during use of the AI processor upon completion of the training period.

In a third aspect of the present technology, a memory stack may be provided which includes all non-volatile memory and a memory controller. Such a stack is referred to herein as a high bandwidth flash (HBF) stack. In embodiments, a processor may be mounted on a printed circuit board. One or more of the HBF stacks may then be mounted alongside the processor, together with one or more HBM stacks. In one example, the HBF stacks may be used by the processor for read operations, and the HBM stacks may be used for write operations.

In a fourth aspect of the present technology, a memory stack may be provided which includes a mixture of non-volatile memory and volatile memory, together with a memory controller. Such a stack is referred to herein as a hybrid HBF stack. In embodiments, a processor may be mounted on a printed circuit board. One or more of the hybrid HBF stacks may then be mounted alongside the processor. A hybrid HBF stack may include different combinations of volatile and non-volatile memory dies, depending on the capacity and bandwidth needs of the processor. In one example, the non-volatile memory dies of the hybrid HBF stacks may be used by the processor for read operations, and the volatile memory dies of the hybrid HBF stacks may be used for write operations.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is +0.15 mm, or alternatively, +2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

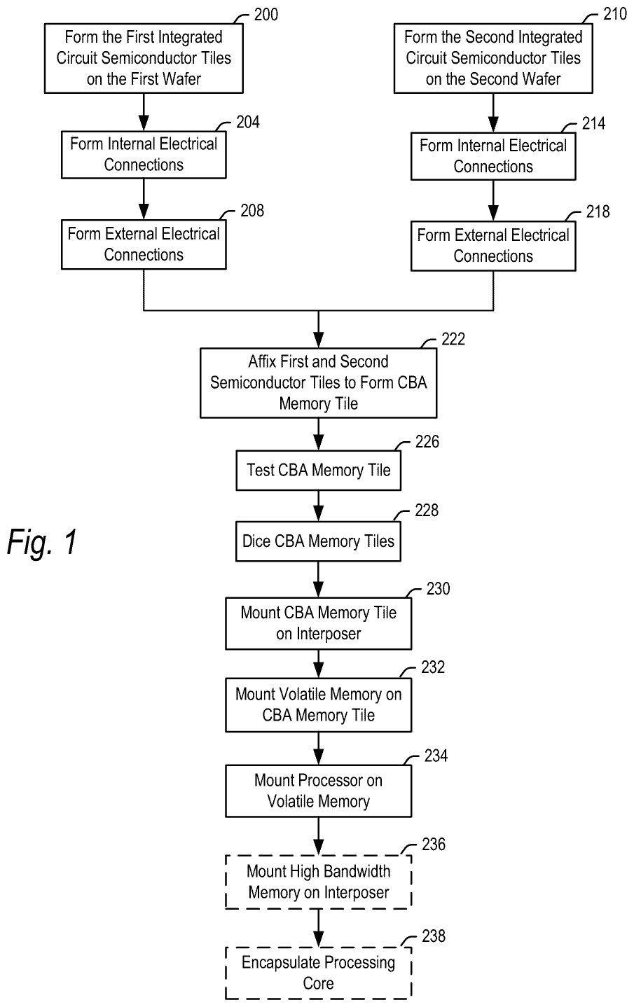

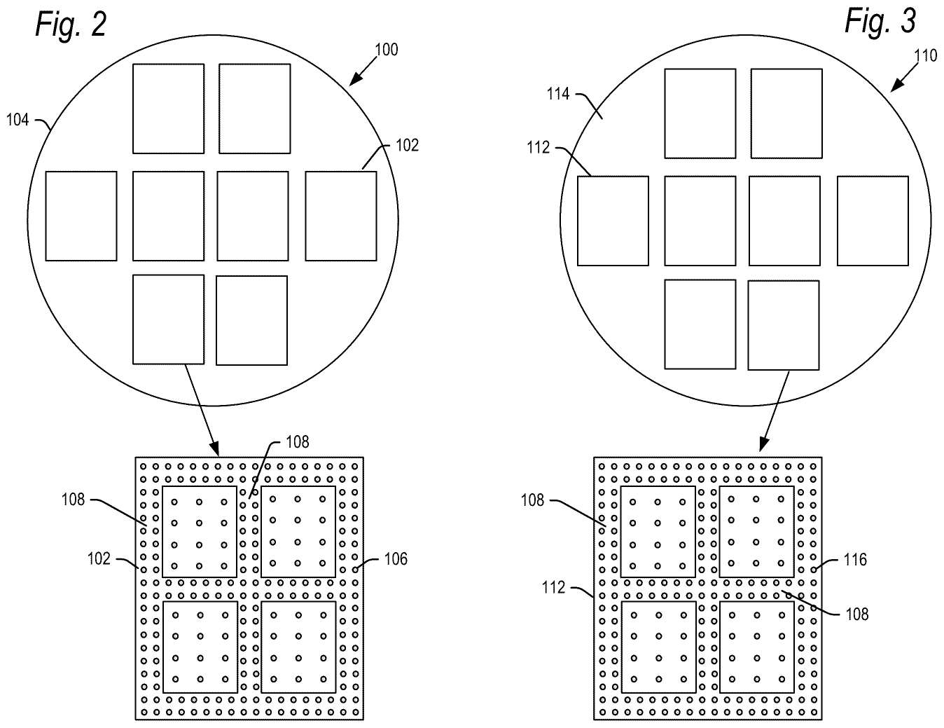

Embodiments of the present technology will now be explained with reference to the flowchart of FIG. 1, and the views of FIGS. 2-40. In step 200, a first semiconductor wafer 100 may be processed into a number of first semiconductor tiles 102 as shown in FIG. 2. The first semiconductor wafer 100 may start as an ingot of wafer material which may be monocrystalline silicon grown according to either a Czochralski (CZ) or floating zone (FZ) process. However, first wafer 100 may be formed of other materials and by other processes in further embodiments.

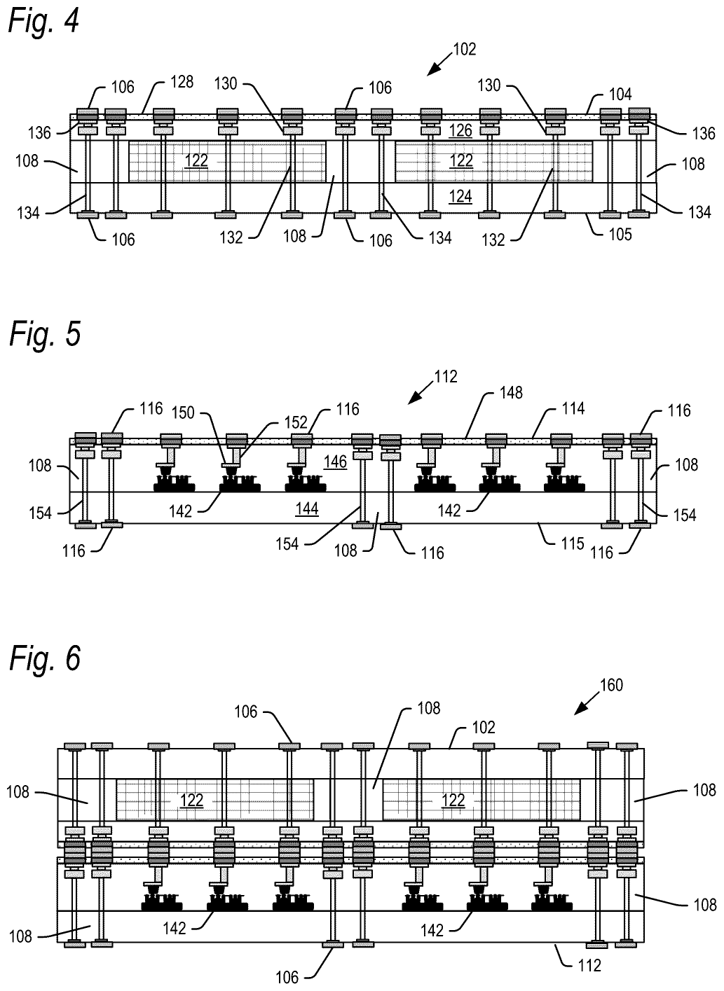

The semiconductor wafer 100 may be cut from the ingot and polished on both the first major planar surface 104, and second major planar surface 105 (FIG. 4) opposite surface 104, to provide smooth surfaces. The first major surface 104 may undergo various processing steps to divide the wafer 100 into the respective first semiconductor tiles 102, and to form integrated circuits of the respective first semiconductor tiles 102 on and/or in the first major surface 104. FIG. 2 further shows detail of a single semiconductor tile 102 including a pattern of micro-bump pads 106 and passthrough zones 108 as explained below.

The processing of wafer 100 in step 200 may include the formation of integrated circuit memory cell array 122 formed in a dielectric substrate including layers 124 and 126 as shown in the cross-sectional edge view of FIG. 4. A reticle may be used to transfer an integrated circuit pattern for a single semiconductor tile 102 in a photolithography process. The patterned wafer can then undergo various processes such as etching, ion implantation, and deposition to create the actual semiconductor components and interconnections needed to build the integrated circuits of a semiconductor tile 102. In embodiments, the integrated circuits may be a memory cell array 122 formed as a 3D stacked memory structure having strings of memory cells formed into layers.

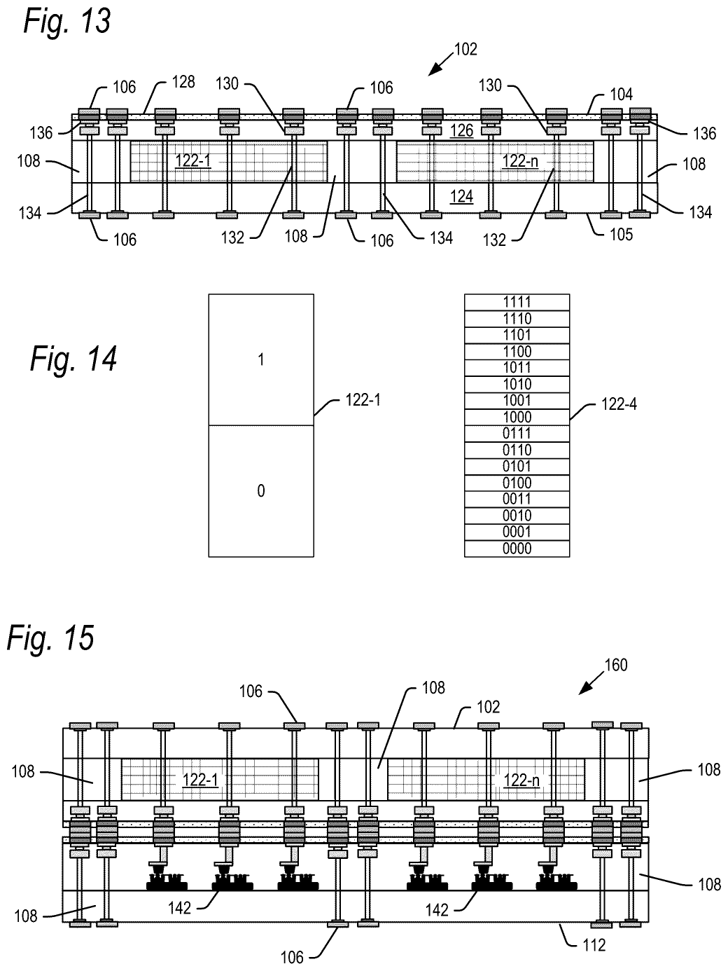

In embodiments, the memory cell array 122 may be formed as a NAND memory, such as for example a BICS (Bit-Cost Scalable) memory. Other types of memory are possible, including for example MRAM. In embodiments, each of the memory cells in the array may be partitioned as an SLC, MLC, TLC or QLC. However, in accordance with aspects of the present technology explained below with respect to FIGS. 13-18, some of the memory cells may be partitioned as SLC, while other memory cells may be partitioned as one or more of MLC, TLC or QLC. It is further understood that the first semiconductor tile 102 may be processed to include integrated circuits other than a 3D stacked memory structure. A passivation layer 128 may be formed on top of the upper dielectric film layer 126.

Semiconductor processing is trending toward smaller and smaller semiconductor dies. In conventional semiconductor processing, a single reticle may include the pattern for multiple semiconductor dies, and the reticle may be used to define hundreds, if not thousands, of semiconductor dies on a single wafer. The semiconductor tiles 102 go counter to this trend. The semiconductor tiles 102 may be the size of an entire reticle, and the reticle is used to form a relatively small number of semiconductor tiles on the wafer 100. As explained below, the size of a semiconductor tile 102 may for example be 32 mm by 25 mm. However, it is understood that the size of a semiconductor tile 102 may vary in further embodiments, and a single reticle may have the pattern for more than one semiconductor tile 102 in further embodiments.

After formation of the memory cell array 122, internal electrical connections may be formed within the first semiconductor tile 102 in step 204. The internal electrical connections may include multiple layers of metal interconnects 130 and vias 132 formed sequentially through layers of the dielectric film 126. As is known in the art, the metal interconnects 130, vias 132 and dielectric film layers 126 may be formed for example by damascene processes a layer at a time using photolithographic and thin-film deposition processes. The photolithographic processes may include for example pattern definition, plasma, chemical or dry etching and polishing. The thin-film deposition processes may include for example sputtering and/or chemical vapor deposition. The metal interconnects 130 may be formed of a variety of electrically conductive metals including for example copper and copper alloys as is known in the art, and the vias 132 may be lined and/or filled with a variety of electrically conductive metals including for example tungsten, copper and copper alloys as is known in the art.

As seen for example in FIG. 4, the metal interconnects 130 and vias 132 may be formed to and through the memory cell array 122 to carry signals to and from the memory cell array 122. However, as noted, semiconductor tile 102 may include certain areas, referred to herein as passthrough zones 108, which are devoid of memory cells or other integrated circuits. These zones 108 include TSVs 134. The TSVs 134 may include metal interconnects and vias and may be formed in the same manner as metal interconnects 130 and vias 132 through one or more dielectric layers as described above. In FIGS. 2 and 4, the TSVs 134 and bump pads 106 are more densely packed within the passthrough zones 108, as compared to the interconnects 130, vias 132 and bump pads 106 outside of the zones 108. However, as explained below, the density of the TSVs 134 and bump pads inside the passthrough zones 108 may be the same or less than the density of interconnects 130, vias 132 and bump pads 106 outside of the zones 108.

In step 208, micro-bump pads 106 may be formed on the major planar surfaces 104 and 105 of the first semiconductor tiles 102. As shown in FIGS. 2 and 4, these bump pads may be formed on top of and/or on the bottom of vias 132 and TSVs 134. As is also explained below, the bump pads 106 are provided for transferring signals to and from the semiconductor tile 102. The bump pads may be etched into the passivation layer 128, and each bump pad 106 may be formed over a liner 136. As is known in the art, the bump pads 106 may be formed for example of copper, aluminum and alloys thereof, and the liner 136 may be formed for example of a titanium/titanium nitride stack such as for example Ti/TiN/Ti, though these materials may vary in further embodiments. The bump pads 106 and liner 136 may be applied by vapor deposition and/or plating techniques. The integrated circuit memory arrays 122 may be electrically connected to the bump pads 106 by the metal interconnects 130 and vias 132.

FIG. 2 shows semiconductor tiles 102 on wafer 100, and bump pads 106 in a pattern on one of the semiconductor tiles 102. The number of first semiconductor tiles 102 shown on wafer 100 in FIG. 2 is for illustrative purposes, and wafer 100 may include more or less first semiconductor tiles 102 than are shown in further embodiments. Similarly, the pattern of bump pads 106, as well as the number of bump pads 106, on the first semiconductor tile 102 are shown for illustrative purposes. Each first tile 102 may include more bump pads 106 than are shown in further embodiments, and may include various other patterns and densities of bump pads 106.

Before, after or in parallel with the formation of the first semiconductor tiles on wafer 100, a second semiconductor wafer 110 may be processed into a number of second semiconductor tiles 112 in step 210 as shown in FIG. 3. The semiconductor wafer 110 may start as an ingot of monocrystalline silicon grown according to either a CZ, FZ or other process. The second semiconductor wafer 110 may be cut and polished on both the first major surface 114, and second major surface 115 (FIG. 5) opposite surface 114, to provide smooth surfaces. The first major surface 114 may undergo various processing steps to divide the second wafer 110 into the respective second semiconductor tiles 112, and to form integrated circuits of the respective second semiconductor tiles 112 on and/or in the first major surface 114. FIG. 3 further shows detail of a single semiconductor tile 112 including a pattern of micro-bump pads 116 and passthrough zones 108 as explained below.

In one embodiment, the second semiconductor tiles 112 may be processed to include integrated circuits 142 formed in a dielectric substrate including layers 144 and 146 as shown in the cross-sectional edge view of FIG. 5. Integrated circuits 142 may be configured as logic circuits to control read/write operations for one or more integrated memory cell arrays 122. The logic circuits may be fabricated using CMOS technology, though the logic circuits may be fabricated using other technologies in further embodiments. The second semiconductor tiles 112 may include other and/or additional integrated circuits in further embodiments as explained below. A passivation layer 148 may be formed on top of the upper dielectric film layer 146.

After formation of the CMOS logic circuits 142, internal electrical connections may be formed within the second semiconductor tile 112 in step 204. The internal electrical connections may include multiple layers of metal interconnects 150 and vias 152 formed sequentially through layers of the dielectric film 146. The metal interconnects 150, vias 152 and dielectric film layers 146 may be formed in the same manner as interconnects 130, vias 132 and dielectric film layer 126 described above for tiles 102.

As seen for example in FIG. 4, the metal interconnects 150 and vias 152 may be connected to the CMOS logic circuits 142 to carry signals to and from the logic circuits 142. However, as noted, semiconductor tile 112 may include passthrough zones 108, which are devoid of the CMOS logic or other integrated circuits. The size and pattern of passthrough zones 108 in semiconductor tiles 112 may match the size and pattern of passthrough zones 108 in semiconductor tiles 102. The passthrough zones 108 in tile 112 may include TSVs 154. The number and pattern of TSVs 154 may match the number and pattern of TSVs 134 described above.

In step 208, micro-bump pads 116 may be formed on the major planar surfaces 114 and 115 of the second semiconductor tiles 112. As shown in FIGS. 3 and 5, these bump pads may be on top of and/or below vias 152 and TSVs 154. As is also explained below, the bump pads 116 are provided for transferring signals to and from the semiconductor tile 112. The bump pads may be etched into the passivation layer 148, and may include liners 156. Bump pads 116 and liners 156 may be formed in the same manner as bump pads 106 and liners 136 described above. The CMOS logic circuits 142 may be electrically connected to the bump pads 116 by the metal interconnects 150 and vias 152.

FIG. 3 shows semiconductor tiles 112 on wafer 110, and bump pads 116 in a pattern on one of the semiconductor tiles 112. The number of second semiconductor tiles 112 shown on wafer 110 in FIG. 3 is for illustrative purposes, and wafer 110 may include more or less second semiconductor tiles 112 than are shown in further embodiments. Similarly, the pattern of bump pads 116, as well as the number of bump pads 116, on the second semiconductor tile 112 are shown for illustrative purposes. Each second tile 112 may include more bump pads 116 than are shown in further embodiments, and may include various other patterns and densities of bump pads 116.

Once the fabrication of first and second semiconductor tiles 102 and 112 is complete, the first and second semiconductor wafers 110 and 110 may be affixed to each other in step 222 so that the respective memory tiles 102 are bonded to the CMOS logic circuit tiles 112. Each pair of bonded tiles 102, 112 are referred to herein as a CMOS bonded to array (CBA) memory tile 160. An example of the completed CBA memory tile 160 is shown for example in the cross-sectional edge view of FIG. 6. To bond the tiles 102, 112, the first semiconductor wafer 100 may be flipped over (relative to the view of FIG. 4), and bump pads 106 and 116 of the respective tiles 102 and 112 may be physically and electrically coupled to each other. As shown and noted, the number and pattern of bump pads 106 may match the number and pattern of bump pads 116 so that the pads align with each other when the tiles 102, 112 are coupled together. In embodiments where the number and pattern of bump pads 106, 116 are not symmetrical about a central vertical axis through the tiles, the number and pattern of bump pads 106 may be the mirror image of the number and pattern of bump pads 116 so that the pads 106, 116 align when tile 102 is flipped over.

The first and second semiconductor tiles 102, 112 in the CBA memory tile 160 may be bonded to each other by initially aligning the bump pads 106 and 116 on the respective tiles 102, 112 with each other. Thereafter, the bump pads 106, 116 may be bonded together by any of a variety of bonding techniques, depending in part on bump pad size and bump pad spacing (i.e., bump pad pitch). The bump pad size and pitch may in turn be dictated by the number of electrical interconnections required for the CBA memory tile 160 as explained below.

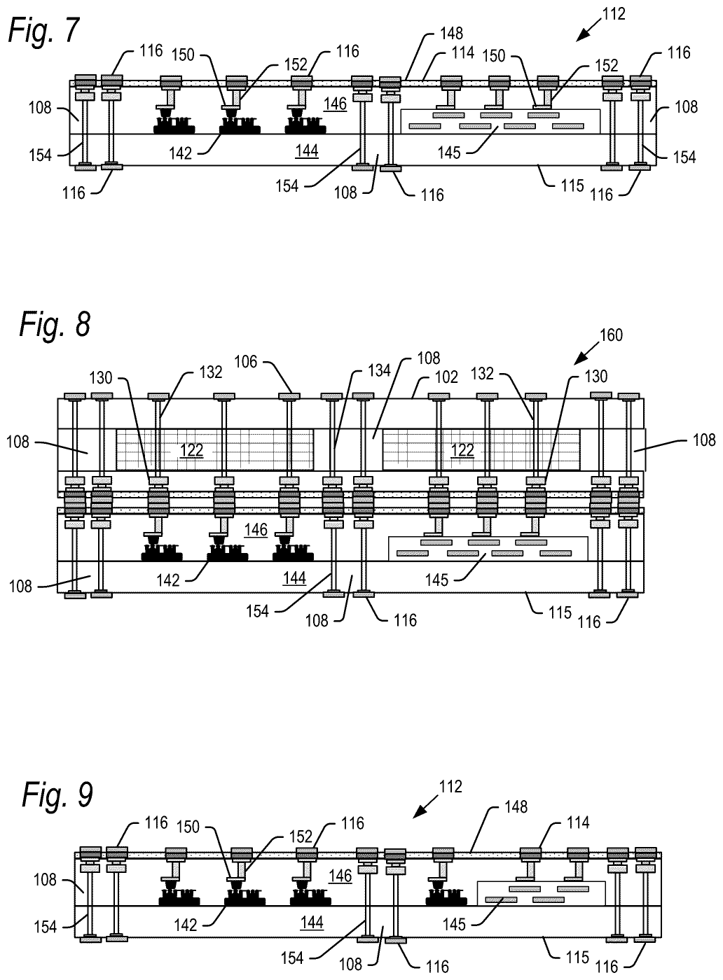

As noted above, while non-volatile memory arrays such as those of semiconductor tile 102 provide large storage capacity, for example 2 TB or more, they are also subject to degradation during write operations. As such, despite the advantages of high storage capacity, non-volatile memory arrays are not ideal for use during the training phase of AI processors. The present technology addresses this problem by providing a CBA memory tile 160 that includes both non-volatile memory and volatile memory. While not as efficient from a storage capacity standpoint, volatile memories are not subject to the same degradation during write operations as non-volatile memories. Such an embodiment will now be described with reference to FIGS. 7-12.

It is a feature of a CMOS bonded array semiconductor device that the size needed for the CMOS logic circuitry is small as compared to the size of the non-volatile memory. This is especially true on a large CMOS bonded array semiconductor device such as CBA memory tile 160. In accordance with aspects of the present technology, the leftover space within the CMOS semiconductor tile 112, not needed for the logic control circuitry 142, may be processed into volatile memory.

In the embodiment shown in FIG. 7, the CMOS semiconductor tile 112 is processed to include CMOS logic circuits 142 in dielectric layers 144 and 146 as described above, the CMOS semiconductor tile 112 includes metallization layers 150, vias 152 and TSVs 154 (in passthrough zones 108) as described above. However, the CMOS semiconductor tile 112 further incudes volatile memory 145, shown schematically in the cross-sectional view of FIG. 7. The volatile memory 145 may for example be DRAM memory cells, but the tile 112 may be processed to include other types of volatile memory in further embodiments, including for example SRAM and SDRAM.

The integrated circuit transistors and capacitors that define the volatile memory 145 may be formed at the same (or different) time as the integrated circuit transistors that define the logic circuitry 142. As with the logic circuitry 142 formed in dielectric layer 146, the transistors and capacitors of the volatile memory may be formed in the dielectric layer 146 using photolithography. However, different deposition and patterning processes are used to define the volatile memory 145 as compared with the logic circuitry 142. The result is that parts of the CMOS semiconductor tile 112 are processed to include the logic circuitry 142, while other parts of the CMOS semiconductor tile 112 are processed to include volatile memory 145.

The metallization layers 150 and vias 152 may be used to electrically couple both the logic circuitry 142 and volatile memory 145 to micro-bump pads 116 on at least the first planar surface 114 of semiconductor tile 112 as described above. Upon completion of the tile 112, the pads 116 may be bonded to the micro-bump pads 106 of the first semiconductor tile 102 as described above and hereinafter in more detail to complete the formation of the CBA memory tile 160. Bonding of the pads 106 and 116 electrically couples the volatile memory 145 of the second semiconductor tile 112 to and/or through the first semiconductor tile 102 using the metallization layers 130, vias 132 and/or TSVs 134 in the first semiconductor tile 102.

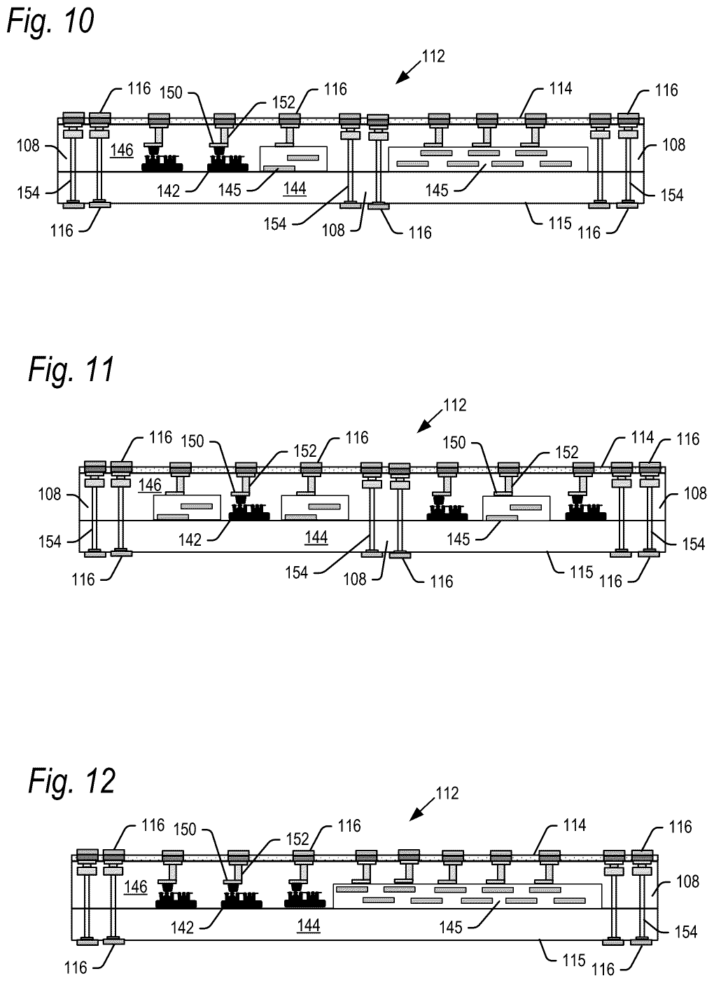

The amount of the first semiconductor tile 112 used for volatile memory 145 as compared to logic circuitry 142 may vary in embodiments. FIGS. 7 and 8 show about an equal division between logic circuitry 142 and volatile memory 145. The cross-sectional view of FIG. 9 shows more area used for logic circuitry 142 as compared to volatile memory 145. And the cross-sectional view of FIG. 10 shows more area used for volatile memory 145 as compared to logic circuitry 142. While the logic circuitry 142 is shown on one side (the left side) and the volatile memory 145 is shown on the other side (the right side) in FIGS. 7-10, the logic circuitry and volatile memory may be interspersed with each other to a greater extent in further embodiments, for example as shown in the cross-sectional view of FIG. 11.

The embodiment of FIGS. 7-11 includes passthrough zones 108 including TSVs 154 and devoid of logic circuitry 142 and volatile memory 145. However, in a further embodiment shown in the cross-sectional view of FIG. 12, some or all of the passthrough zones 108 may be omitted, leaving additional space for the formation of volatile memory 145 and/or logic circuitry 142.

A hybrid CMOS semiconductor tile 112 including both logic circuitry 142 and volatile memory 145 provides a number of advantages. First, logic circuitry 142 provides various control functions for both the non-volatile memory array 122 and the volatile memory 145. Additionally, the volatile memory array 145 provides a low latency, high bandwidth buffer or cache memory for use by the specialized processor explained below. Moreover, as noted in the Background, the training phase of an AI processor involves a very large number of read/writes to an associated memory, which write operations can degrade a non-volatile memory. However, volatile memory does not have the same degradation with high volume write operations. Thus, the volatile memory 145 allows the CBA memory tile 160 to be used not only in the inference stage of the AI processor explained below, but also extensively during the training phase of the AI processor. In one example, the volatile memory 145 of CBA memory tile 160 can provide about 10 GB of storage capacity for use during the training and inference stages of the AI processor. The storage capacity of the volatile memory 145 may be greater or lesser than 10 GB in further embodiments.

In a further aspect of the present technology, the non-volatile memory 122 may additionally or alternatively be customized to reduce wear to the memory during the training phase of the AI processor. In particular, as noted above, non-volatile memory arrays are conventionally partitioned to include one type of memory cell; either single-level cells (SLCs), multi-level cells (MLCs), triple-level cells (TLCs) or quad-level cells (QLCs). While QLCs provide the highest storage capacity, they are also subject to the greatest degradation during write operations given the large amount of data that is written to such cells. As such, despite the advantages of high storage capacity, QLCs (and other multi-bit cells) are not ideal for use during the training phase of AI processors. The present technology addresses this problem by providing a hybrid non-volatile memory array including some cells partitioned as SLCs and other cells partitioned as one or more of MLCs, TLCs and QLCs. Such aspects of the present technology will now be described with reference to FIGS. 13-18.

FIG. 13 is a cross-sectional view of the first semiconductor tile 102 including a hybrid memory array 122 that includes a first memory array portion 122-1 partitioned as SLCs and at least a second memory array portion 122-n partitioned as one or more of MLCs, TLCs and/or QLCs. All other components of semiconductor tile 102 shown in FIG. 13 may be fabricated as described above. FIG. 14 is an illustration of the memory cells in the first memory array portion 122-1 and the memory cells in one example of the second memory array portion 122-n. As shown, the portion 122-1 includes a single bit cell allowing for 1 bit of data, and the portion 122-n (in this example) is partitioned as a QLC including a four bit cell allowing for 16 bits of data.

FIG. 15 shows the tile 102 including hybrid memory array 122 affixed to the second semiconductor tile 112 to form a completed CBA memory tile 160. In the embodiment shown, the second semiconductor tile 112 includes only CMOS logic control circuitry 142. However, in further embodiments, the tile 112 may alternatively be the hybrid CMOS semiconductor tile including both logic control circuitry 142 and volatile memory 145 described above.

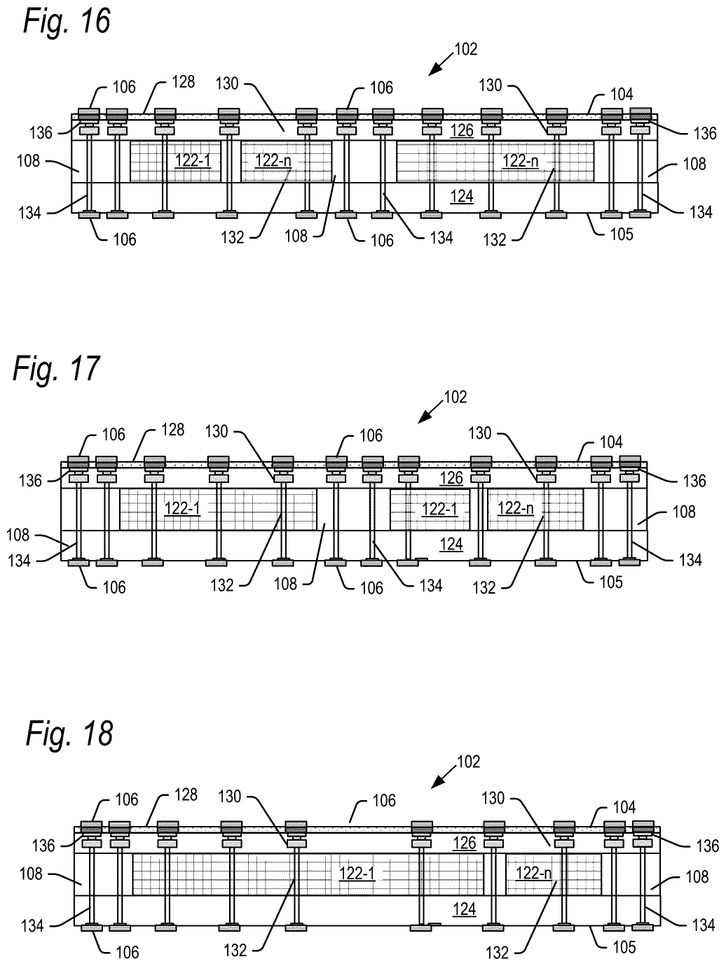

In FIGS. 13 and 15, there is an equal division of the hybrid memory array 122 between the SLC memory array portion 122-1 and the memory array portion 122-n including one or more of MLC, TLC and QLC. In a further embodiment shown in the cross-sectional view of FIG. 16, the SLC memory array portion 122-1 may be smaller than the memory array portion 122-n. In a further embodiment shown in the cross-sectional view of FIG. 17, the SLC memory array portion 122-1 may be larger than the memory array portion 122-n.

While the SLC memory array portion 122-1 may still be subject to degradation with write operations over time, it is subject to less degradation than the memory array portion 122-n. In one example, the SLC memory array portion 122-1 may provide 500 GB of storage capacity, and can support a wear-out cycle of about 1.2 million write operations. This storage capacity and wear-out cycle are sufficient to allow the SLC memory array portion 122-1 of CBA memory tile 160 to entirely support the AI processor during its training phase. Upon completion of the training phase, the SLC memory array portion 122-1 may still be available for the inference phase of the AI processor, but even if the portion 122-1 were not used after training, the memory array portion 122-n of the CBA memory tile 160 may provide 1.5 TB or more of storage capacity, which is sufficient to support the AI processor during the inference phase.

The embodiment of FIGS. 13 and 15-17 includes passthrough zones 108 including TSVs 134 and devoid of memory arrays 122. However, in a further embodiment shown in the cross-sectional view of FIG. 18, some or all of the passthrough zones 108 may be omitted, leaving additional space for the formation of SLC memory array portions 122-1 and/or memory array portions 122-n including MLCs, TLCs and/or QLCs.

In the embodiments of the hybrid memory array described above with respect to FIGS. 13-18, the first semiconductor tile 102 including the hybrid memory array 122 is bonded to the second semiconductor tile 112 including the CMOS logic circuitry 142 and, possibly, volatile memory 145. In a further embodiment, it is possible that the semiconductor tile 102 including the hybrid memory array 122 shown in FIGS. 13 and 16-18 may be used by itself, without the second semiconductor tile 112. In such embodiments, a separate controller die such as an ASIC may be provided to control the operation of the hybrid memory array 122 of the semiconductor tile 102.

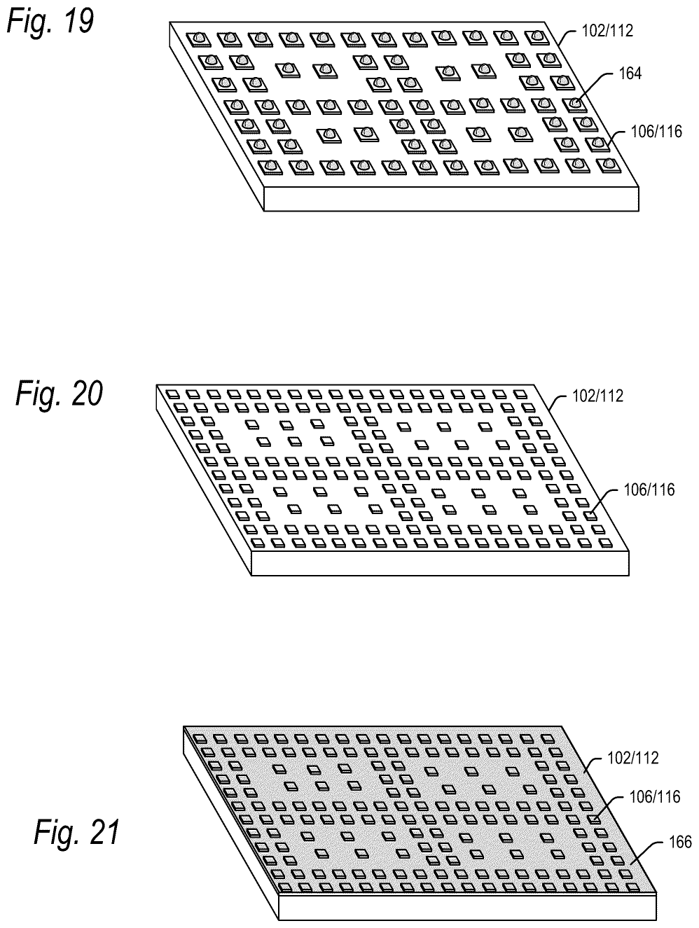

The perspective and cross-sectional views of FIGS. 19-21 will be used to show different schemes for bonding together the first and second semiconductor dies 102 and 112 (according to any of the above-described embodiments). In one embodiment shown in the perspective view of FIG. 19, one or both sets of bump pads 106, 116 on the mating surfaces of the first and second tiles 102, 112 may include micro-bumps 164 applied to the surfaces of pads 106 and/or 116. A small, controlled amount of solder, copper, bronze, gold or other metal may be applied to bump pad 106 and/or to bump pad 116 of a pair of bump pads to be joined. The respective bump pads may be coupled to each other by micro-bumps 164 using for example thermo-compression. In example, the bump pads 106, 116 may be about 50 μm square. Again, the number and pattern of bump pads 106/116 shown in FIG. 19 is for illustrative purposes only and may vary in further embodiments.

Instead of using micro-bumps 164, the pads 106 and 116 of tiles 102 and 112 may be bonded to each other without solder or other added material, in a so-called Cu-to-Cu bonding process. Such an example is shown in the perspective view of FIG. 20. In a Cu-to-Cu bonding process, the bump pads 106, 116 are controlled to be highly planar and formed in a highly controlled environment largely devoid of ambient particulates. Under such properly controlled conditions, the bump pads 106, 116 are aligned and pressed against each other to form a mutual bond based on oxide bonding. Such bonds may be formed at room temperature, though an annealing process may be performed to heat and cool the bump pads under controlled conditions to further improve the bond. In embodiments using Cu-to-Cu bonding, the bump pads 106, 116 may be about 5 μm square, and the bumps 106, 116 may be spaced from each other with a pitch of 10 μm to 20 μm. The pads and/or pitch may be larger or smaller than that in further embodiments. While this process is referred to herein as Cu-to-Cu bonding, this term may also apply even where the bump pads 106, 116 are formed of materials other than copper.

In a further embodiment shown in the perspective view of FIG. 21, the Cu-to-Cu bond may be enhanced by providing a film layer 166 on the surface 104 of the first tiles 102, and/or a film layer 166 on the surface 114 of the second tiles 112. Such a film layer 166 is provided around the bump pads 106, 116. When the first and second tiles 102, 112 are brought together, the bump pads 106, 116 may bond to each other using oxide bonding and annealing, and the film layers 166 on the respective tiles may bond to each other using adhesion and/or surface tension. Such a bonding technique may be referred to as hybrid bonding. In embodiments using hybrid bonding, the bump pads 106, 116 may be about 5 μm square, and the bumps 106, 116 may be spaced from each other with a pitch of 5 μm to 10 μm. The pads and/or pitch may be larger or smaller than that in further embodiments.

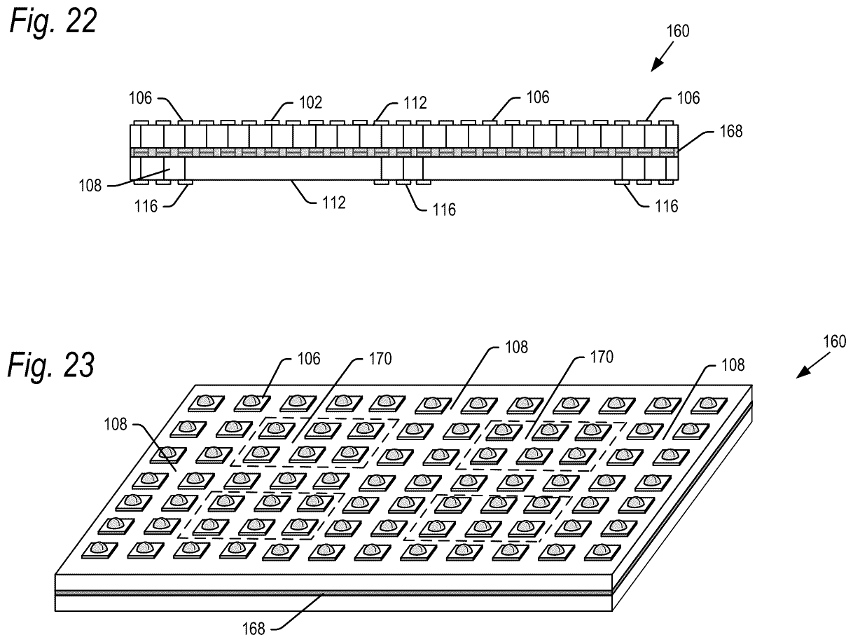

As noted, once coupled to each other in step 222, the first semiconductor tile 102 and the second semiconductor tile 112 together form a CBA memory tile 160. The tile 160 may be operationally tested in step 226 as is known, for example with read/write and burn in operations. The tiles 160 may be diced from the joined wafers 100, 110 in step 228. Examples of the CBA memory tile 160 are shown in the cross-sectional edge views of FIGS. 6, 8 and 15 described above, as well as in the edge and perspective views of FIGS. 22 and 23. As shown, once coupled together, the bump pads 106 on the surface 105 of tile 102 and the bump pads 116 on surface 115 of tile 112 may remain exposed. These exposed bump pads 106, 116 may be used as explained below. Again, the views of FIGS. 22 and 23 are merely illustrative examples. The number, pattern and/or densities of bump pads 106, 116 shown may vary in further examples.

In one embodiment described above, a film 166 (FIG. 21) may be provided on a surface of one of the first and second tiles 102, 112. Where no such film is initially provided, a space between the first and second tiles of the CBA memory tile 160 may be under filled with an epoxy or other resin or polymer 168 (FIGS. 22 and 23). The under-fill material 168 may be applied as a liquid which then is cured into a solid layer. This under-fill step protects the electrical connections between the first and second tiles 102, 112, and further secures the second tile 112 onto the first tile 102. Various materials may be used as under-fill material 168, but in embodiments, it may be Hysol epoxy resin from Henkel Corp., having offices in California, USA.

As noted above, the CBA memory tile 160 includes passthrough zones 108. In the embodiments shown for example in FIGS. 2 and 3, the passthrough zones 108 comprise a border around the periphery of tile 160, and a cross pattern extending horizontally and vertically through a center of tile 160. It is understood that the passthrough zones may comprise other patterns on tile 160 in further embodiments. As noted, there are no memory array circuits 122, logic circuits 142 or volatile memory 145 in the passthrough zones 108.

The bump pads 106 in the passthrough zones 108 are used to transfer, or passthrough, power, ground and data signals to and from the processor, through the CBA memory tile 160. In one embodiment, the passthrough zones 108 around the periphery of tile 160 may be used for signal exchange between the processor and high bandwidth memory also mounted on the interposer, through the tile 160. Given the large numbers of these connections, these periphery passthrough zones 108 may have a width of about 1.25 mm, with 25 rows of bump pads across the width having a pitch of about 40 μm. The pitch of the bump pads along the length may be about 60 μm. In this embodiment, the cross pattern of passthrough zones 108 through the center of the tile 160 may be used for power and ground signals. These cross pattern passthrough zones 108 may have a width of about 500 μm, with 10 rows of bump pads across the width having a pitch of about 50 μm. The pitch of the bump pads along the length may be about 125 μm. Each of these dimensions is by way of example and may vary, proportionately and disproportionately to each other, in further embodiments. It is further understood that the portions of the passthrough zones used for signals, power and ground may also vary in further embodiments.

It is understood that the size of the passthrough zones may be increased or decreased based on the requirements of the processing core. Where more passthrough connections are needed, the size of the passthrough zones may be increased and the number of direct connections between the tile 160 and processor may be decreased. Where less passthrough connections are needed (or more direct connections between the tile 160 and processor are needed), the size of the passthrough zones may be decreased and the number of direct connections between the tile 160 and processor may be increased.

The areas 170 (FIG. 23) are the areas of tile 160 including the memory array circuits 122, logic circuits 142 and volatile memory 145, and are positioned outside of passthrough zones 108. In the embodiment shown, the passthrough zones divide the areas 170 into four quadrants. Again, this is one of many possible configurations of the areas 170 including the memory array circuits 122, logic circuits 142 and volatile memory 145. While FIGS. 2 and 3, for example, show a greater density of micro-bump pads 106 in the passthrough zones 108 than in areas 170, the density of the micro-bumps 106 in the passthrough zones 108 may be less than or equal to the density of micro-bumps 106 in areas 170.

As explained below, the CBA memory tile 160 may be mounted on a signal conducting medium, such as a printed circuit board (PCB), a substrate, or an interposer, and a processor may be mounted atop the CBA memory tile 160. The terms PCB, substrate and interposer may be used interchangeably herein, and refer to a means for electrically interconnecting one or more modules or circuits to each other, such as coupling a processor and/or CBA memory tile to one or more semiconductor memory dies. Further, the use of one term over another does not impute specific characteristics to the “signal carrying medium,” such as base materials, number of layers, etc. It is believed that one of skill in the art will be able to understand that where, for instance, the term interposer is used, that interposer also may refer to a substrate or a printed circuit board. The bump pads 116 in the areas 170 allow the processor to be directly coupled to CBA memory tile 160 so that the processor can perform read/write operations to the memory tile 160. Given the large size of the CBA memory tile 160, there is ample room for all of the channels and electrical connections between the processor and CBA memory tile 160.

In embodiments, the spacing between, or pitch, of bump pads 106 in the areas 170 may be 2 μm to 50 μm, depending in part on the bonding technology used. Given this pitch and the large surface area of the CBA tile 160, this allows for about 200,000 direct connections between the tile 160 and the processor. The number of direct connections may be more or less than this number in further embodiments. As discussed below, this allows for high bandwidth, wide-word data direct data transfer to and from the CBA memory tile 160. There may be greater or fewer direct connections in further embodiments.

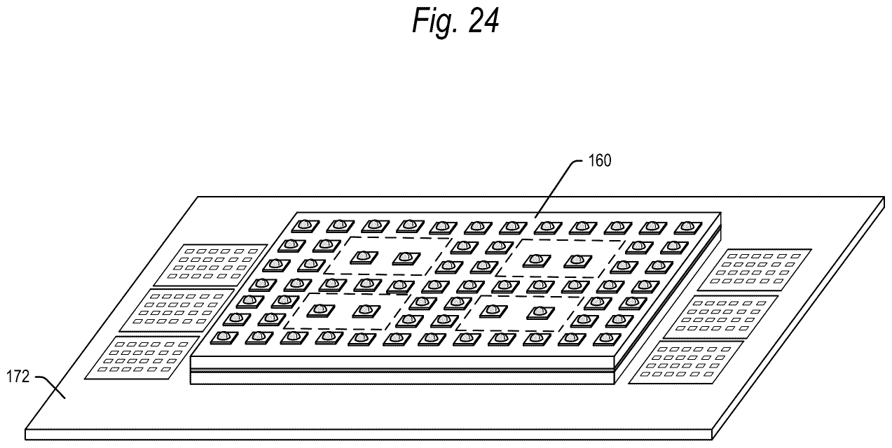

In step 230, the CBA memory tile 160 may be mounted on an interposer 172 as shown in the perspective view of FIG. 24. The CBA memory tile 160 may include first and second semiconductor dies 102 and 112 processed according to any of the above-described embodiments. Interposer 172 may be a signal-carrying medium including multiple conductive layers formed with vias and conductance patterns interspersed between dielectric layers. The interposer may be formed in a silicon wafer, diced into sizes to support the CBA memory tile 160 and high bandwidth memory stacks as explained below. In further embodiments, the CBA memory tiles may be mounted to respective interposers while the interposers remain part of a whole, undiced wafer. The interposer 172 is used to transfer signals to and from the CBA memory tile 160 and the processor mounted thereon as explained hereinafter. Other signal-carrying mediums may be used in further embodiments, including a flexible tape, a substrate or a printed circuit board.

A top surface of the interposer 172 may have a pattern of contact pads (not shown) matching in number and arrangement to the bump pads 116 on a bottom surface 115 of the CBA memory tile 160. The CBA memory tile 160 may be physically and electrically coupled to the interposer 172 by mating the bump pads 116 on the surface 115 of tile 160 with the contact pads on the upper surface of interposer 172. The bond between the bump pads 116 and contact pads of the interposer may be accomplished using any of the methods described above for bonding bump pads 116 and bond pads 106 within the tile 160.

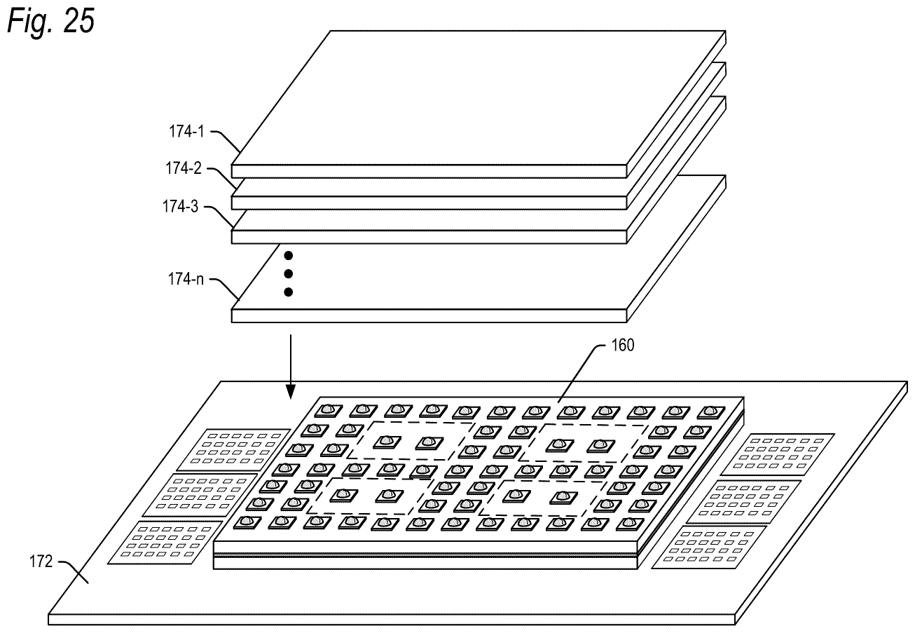

The CBA memory tile 160 provides a large block of memory near to the processor 175 described below, for example 1-4 terabytes. In embodiments, one or more volatile memory tiles 174 may be mounted on top of the CBA memory block in step 232 as shown in FIG. 25 to provide a large block of high speed/high bandwidth memory near the processor 175. In embodiments, each volatile memory tile 174 may have the same length and width (same footprint) as the CBA memory tile 160. In the embodiment shown in FIG. 25, the volatile memory tiles 174 may include tiles 174-1, 174-2, 174-3, . . . , 174-n. However, there may be 1, 2, 3, 4 or more tiles 174 in different embodiments.

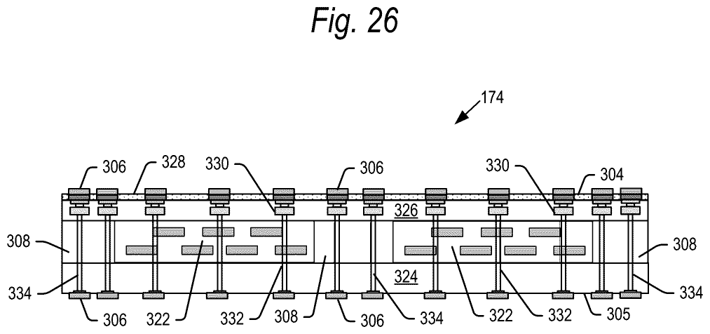

FIG. 26 is a cross-sectional view of an example of a volatile memory tile 174. The memory tiles may be processed in wafer form to include integrated circuit memory cell arrays 322 formed in a dielectric substrate including layers 324 and 326. A reticle may be used to transfer an integrated circuit pattern for a single semiconductor tile 174 in a photolithography process. The patterned wafer can then undergo various photolithography processes to create the transistors, capacitors and metal interconnections needed to build the volatile memory integrated circuits of tile 174. In embodiments, the integrated circuit memory cell array 322 may be formed as DRAM. However, the memory cell array 322 may be a variety of other volatile memories, including for example SRAM and SDRAM. A passivation layer 328 may be formed on top of the upper dielectric film layer 326.

After formation of the memory cell array 322, internal electrical connections may be formed within the volatile memory tile(s) 174. The internal electrical connections may include multiple layers of metal interconnects 330 and vias 332 formed sequentially through layers of the dielectric film 326. The metal interconnects 330 and vias 332 may be formed as described above with respect to metal interconnects 130 and vias 132. As discussed above for CBA tiles 160, the volatile memory tile(s) 174 may include passthrough zones 308, which are devoid of memory cells or other integrated circuits. These zones 308 include TSVs 334 and may match the TSVs 134 in CBA tiles 160 in pattern and configuration. As discussed above, the passthrough zones 308 are provided to allow signals and voltages to pass through the volatile memory tile(s) 174.

Micro-bump pads 306 may be formed on the major planar surfaces 304 and 305 of the volatile memory tile(s) 174. These bump pads may be formed on top of and/or on the bottom of vias 332 and TSVs 334. The micro-bump pads 306 may be formed in the same way and for the same purpose as pads 106 described above. While FIG. 26 shows a pattern of bump pads 306 for illustrative purposes, the pattern of bump pads 306, as well as the number of bump pads 306 may vary in further embodiments.

The bump pads 306 on a bottommost volatile memory tile 174 align with and are bonded to the bump pads 106 on an uppermost surface of the CBA memory tile 160. Moreover, where there are multiple volatile memory tiles 174, the bump pads 306 are used to bond and electrically couple the multiple volatile memory tiles 174 to each other and the CBA memory tile 160. As explained below, it is possible that the volatile memory tiles 174 be omitted in further embodiments.

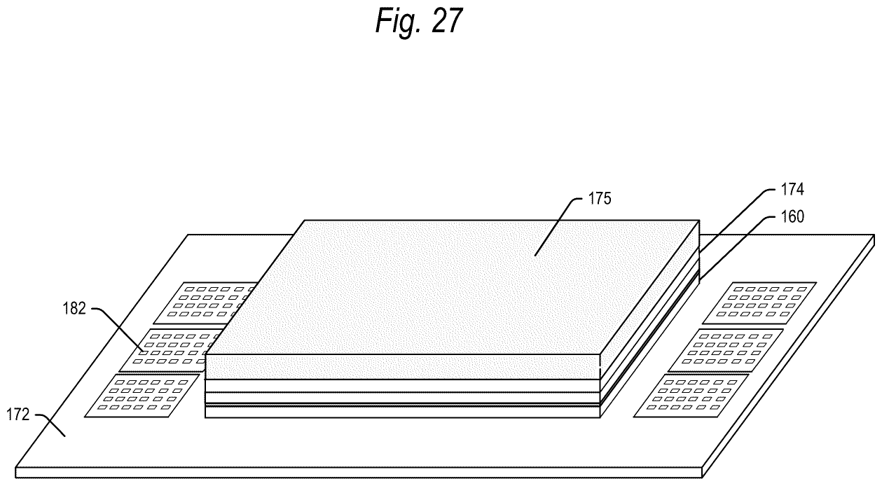

In step 234, a processor 175 may be mounted on top of the one or more volatile memory tiles 174 (or CBA memory tile 160 where tiles 174 are omitted), as shown in the perspective view of FIG. 27, to form an integrated processor/memory core. In embodiments, processor 175 may be a specialized processor such as a graphics processing unit (GPU) or an artificial intelligence (AI) processor capable of parallel processing, sophisticated graphics rendering and/or other high bandwidth, data-intensive tasks. The processor 175 may include multiple processing cores enabling the processor 175 to perform multiple computing tasks simultaneously. In further embodiments, processor 175 may be other types of processors, such a traditional central processing unit.

In embodiments, the processor 175 may have the same footprint as the volatile memory tiles 174 and CBA memory tiles 160. A bottom surface of the processor 175 may have a pattern of contact pads or micro-bumps (not shown) matching in number and arrangement to the bump pads 306 on a top surface of the uppermost volatile memory tile 174. The processor 175 may be physically and electrically coupled to the uppermost volatile memory tile 174 by mating the bump pads of the volatile memory tile with the contact pads on the bottom surface of the processor 175. The bond between the respective bump pads/micro-bumps of the processor 175 and uppermost volatile memory tile may be accomplished using any of the methods described above for bonding of the CBA memory tile 160.

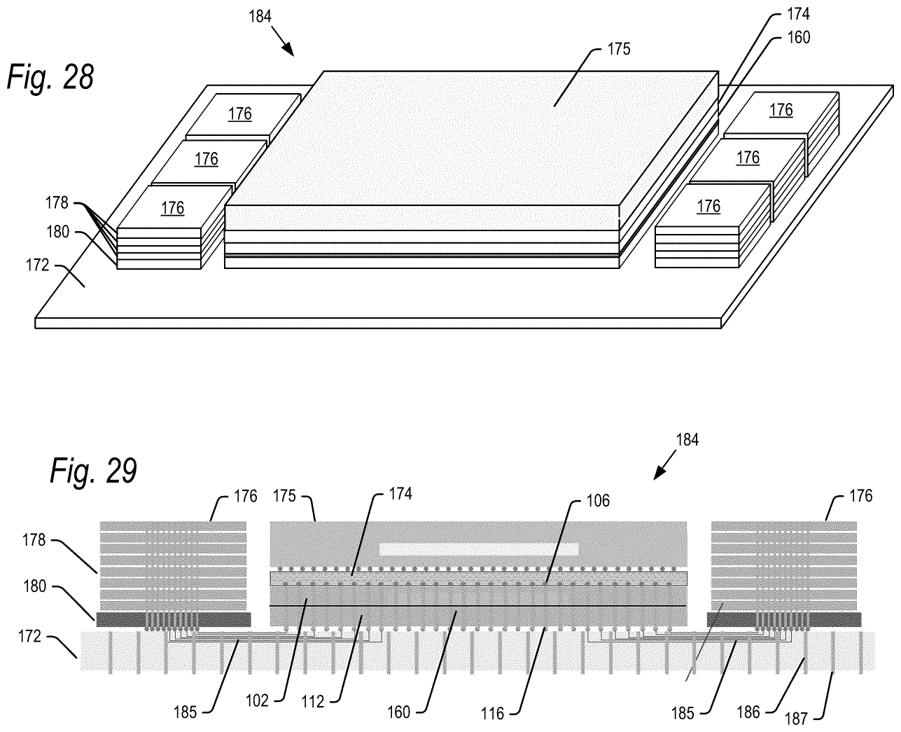

In step 236, high bandwidth memory (HBM) stacks 176 may be mounted around one or more sides of the tiles 160, 174 and processor 175, as shown in the perspective and cross-sectional views of FIGS. 28-29. In embodiments, each HBM stack 176 includes one or more HBM dies 178 mounted on a dedicated HBM controller 180. The number of HBM dies 178 in each stack may vary. Each of the dies 178 in the HBM stack may be volatile memory such as DRAM. The HBM stacks provide high-speed, high-bandwidth, and low-power memory for fast data access to specialized, high-performance processors, such as the GPU or AI processor which may comprise the processor 175. The controller 180 is used to operate and communicate with the dies 178 in each HBM stack 176. While shown at the bottom of each stack in FIG. 17, the controller 180 may be positioned elsewhere in the stack 176 in further embodiments.

In the illustrated embodiment, there are three HBM stacks 176 on each of two opposed sides of the tiles 160, 174 and processor 175. There may be more or less stacks around more or less sides in further embodiments. Each of the dies in stack 176 may be electrically coupled to each other using TSVs, and a bottom surface of the stack 176 may have a pattern of contact pads (not shown) matching in number and arrangement to the contact pads 182 on interposer 172, one of which is numbered in FIG. 16. Each stack 176 may be physically and electrically coupled to pads 182 on interposer 172 as described above with regard to other pad couplings.

FIG. 28 shows a perspective view of a completed integrated processing core 184 including the integrated CBA memory tile 160, one or more volatile memory tiles 174 and processor 175 together with HBM stacks 176 mounted on interposer 172. FIG. 29 is a cross-sectional view of integrated processing core 184 showing internal electrical connections. FIG. 29 for example shows the bump pads, such as bump pads 106, between the CBA memory tile 160 and the volatile memory tile 174, and between the volatile memory tile 174 and the processor 175. The drawing further shows the bump pads 116 between the CBA memory tile 160 and the interposer 172. Electrical traces 185 are further shown within layers of the interposer 172 for electrically coupling the processor 175 to the high bandwidth memory stacks 176 (through the passthrough zones of the CBA memory tile 160 and volatile memory tile 174). Also shown are vias 186 through the interposer 172 coupled to pads or bumps 187 on a bottom surface of the interposer 172 for electrically coupling the processing core 184 to a printed circuit board of a host device (not shown).

In a final step 238, the entire processing core 184 may be encapsulated in a molding compound. The encapsulation step 238 may be omitted in embodiments. As such, step 238 is shown in dashed lines in FIG. 1. It is noted that the tiles 102, 112 of CBA memory tile 160, volatile memory tile 174, the processor 175 and high-bandwidth semiconductor dies 178 are shown in the figures for illustrative purposes only, and the thicknesses of the respective tiles, processor and high-bandwidth semiconductor dies are not drawn to scale in the figures.

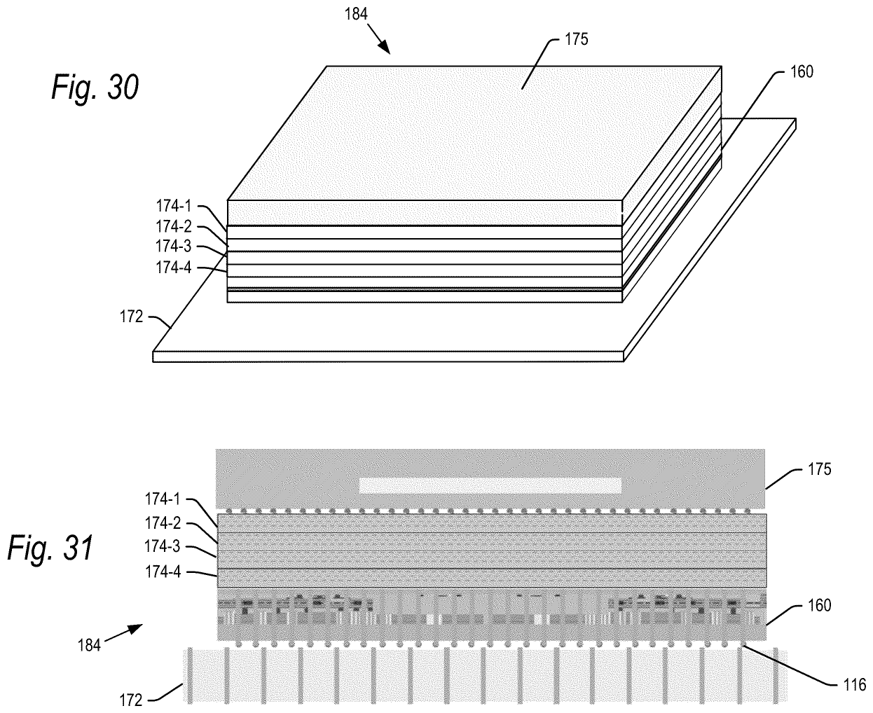

The processing core 184 described above sets forth one example of components, but it is understood that various alternatives and or additions to processing core 184 may be made in further embodiments. For example, in the embodiments described above, the processing core 184 has two ready sources of high bandwidth volatile memory—HBM stacks 176 and volatile memory tile(s) 174. However, where a sufficient number of volatile memory tiles 174 are provided, such as for example four tiles providing 100-200 Gigabytes, the HBM stacks 176 may be partially or completely omitted. As such, step 236 of adding the HBM stacks 176 is shown with dashed lines in FIG. 1. An embodiment where the HBM stacks 176 are completely omitted is shown in perspective view in FIG. 30 and cross-sectional view in FIG. 31.

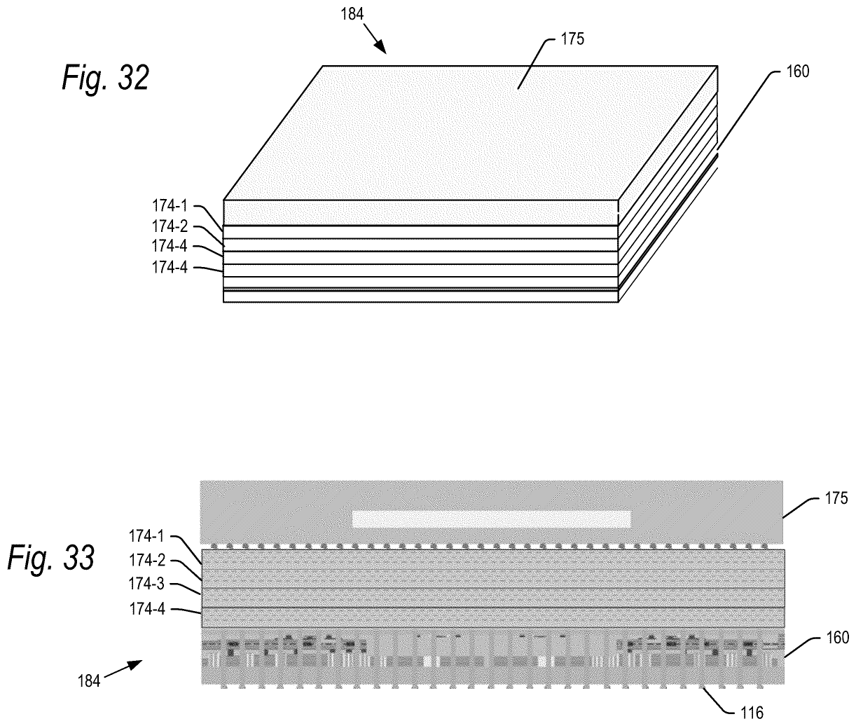

In the embodiment of FIGS. 30 and 31, the integrated processing core 184 is mounted on the interposer 172. However, omission of the HBM stacks 176 also allows omission of the interposer 172. Such an embodiment is shown in perspective view in FIG. 32 and cross-sectional view in FIG. 33. In this embodiment, the CBA memory tile 160 may be configured as a fan-out package (used without a substrate), where the micro-bump pads 116 bottom surface of the CBA memory tile 160 are redistributed (for example in a redistribution layer) to electrically couple the processing core 184 directly to a printed circuit board of a host device (not shown). Omission of the interposer 172 provides advantages such as smaller form factor and lower power requirements.

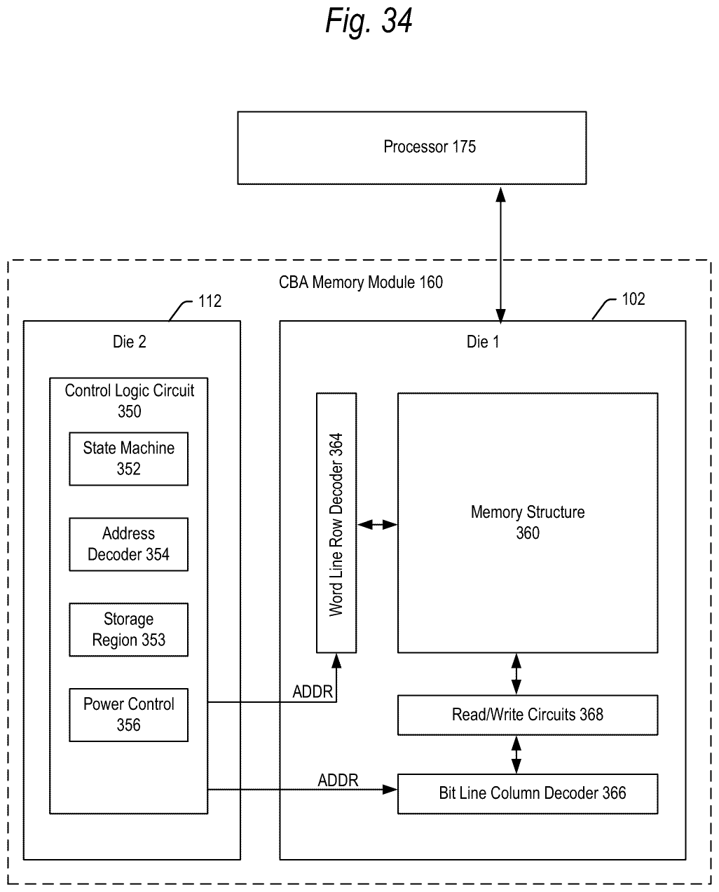

FIG. 34 is a functional block diagram showing further detail of an embodiment of the processing core 184 including CBA memory tiles having memory array tile 102 and CMOS logic circuit tile 112. The memory array tile 102 of the CBA memory tile 160 may include a memory structure 360 of memory cells, such as an array of memory cells, and read/write circuits 368. The CMOS logic circuit tile 112 may include control logic circuitry 350. The memory structure 360 is addressable by word lines via a row decoder 364 and by bit lines via a column decoder 366. The read/write circuits 368 may include multiple sense blocks (sensing circuitry) that allow a page of memory cells to be read or programmed in parallel.

Multiple memory elements in memory structure 360 may be configured so that they are connected in series or so that each element is individually accessible. By way of non-limiting example, flash memory systems in a NAND configuration (NAND memory) typically contain memory elements connected in series. A NAND string is an example of a set of series-connected transistors comprising memory cells and select gate transistors.

A NAND memory array may be configured so that the array is composed of multiple strings of memory in which a string is composed of multiple memory elements sharing a single bit line and accessed as a group. Alternatively, memory elements of memory structure 160 may be configured so that each element is individually accessible, e.g., a NOR memory array. NAND and NOR memory configurations are exemplary, and memory elements may be otherwise configured.

The memory structure 360 can be two-dimensional (2D) or three-dimensional (3D). The memory structure 360 may comprise one or more arrays of memory elements (also referred to as memory cells). A 3D memory array is arranged so that memory elements occupy multiple planes or multiple memory device levels, thereby forming a structure in three dimensions (i.e., in the x, y and z directions, where the z direction is substantially perpendicular and the x and y directions are substantially parallel to the major planar surface of the first semiconductor tile 102).

The memory structure 360 on the first tile 102 may be controlled by control logic circuit 350 on the second tile 112. The control logic circuit 350 may have circuitry used for controlling and driving memory elements to accomplish functions such as programming and reading. The control circuitry 350 cooperates with the read/write circuits 368 to perform memory operations on the memory structure 360. In embodiments, control circuitry 350 may include a state machine 352, an on-chip address decoder 354, and a power control module 356. The state machine 352 provides chip-level control of memory operations. A storage region 353 may be provided for operating the memory structure 360 such as programming parameters for different rows or other groups of memory cells. These programming parameters could include bit line voltages and verify voltages.

The on-chip address decoder 354 provides an address interface between that used by the host device or the memory controller (explained below) to the hardware address used by the decoders 364 and 366. The power control module 356 controls the power and voltages supplied to the word lines and bit lines during memory operations. It can include drivers for word line layers in a 3D configuration, source side select gates, drain side select gates and source lines. A source side select gate is a gate transistor at a source-end of a NAND string, and a drain side select gate is a transistor at a drain-end of a NAND string.

The present technology provides several advantages. The various embodiments described above solve the problem of degradation of non-volatile memories in the training of AI processors, and provide different memory solutions that allow for both training and inference of AI processors.

The various embodiments also provide storage solutions that meet the high capacity, low latency requirements of specialized processors such as AI processors and GPUs. For example, the large size of the non-volatile and volatile memory tiles, matching the size of the processor 175, provides a large memory storage for the processor. In examples, this storage capacity may be about 2 terabytes of storage, which is ample storage for even sophisticated processors such as a GPU or AI processor.

At the same time, the large surface area of the volatile memory tile(s) 174 in direct contact with processor 175, and the small pitch electrical connections over this area, allow for a large number of direct electrical connections resulting in high bandwidth data transfer between the volatile memory tile(s) 174 and processor 175. In examples, the high number of direct electrical connections allow for wide-word data transfer between the volatile memory tile(s) 174 and the processor 175, providing for example 1024 bit data transfer between the volatile memory tile(s) 174 and processor 175. The same high bandwidth rates may be accomplished between the processor 175 and the CBA memory tile 160, and between the processor 175 and the HBM stacks 176. This high bandwidth data transfer supports the parallel processing and high performance needs of sophisticated processors such as a GPU or AI processor. Integrating the processor 175 directly atop the large surface area volatile memory tile(s) 174 and CBA memory tile 160 further provides reduced power requirements and parasitics as compared to conventional processing cores where the non-volatile memory is located remote from the processor.

As another advantage, the TSVs in the passthrough zones allow wide-word data transfer between the processor 175 and the HBM stacks 176, again supporting high bandwidth data transfer between the processor 175 and the HBM stacks 176.

In embodiments described above, the first and second wafers 100, 110 may be diced after formation and bonding of the memory array tiles 102 and CMOS logic circuit tiles 112. The formed CBA memory tile 160 may thereafter be bonded to a processor 175 as described above to form an integrated processing core. In further embodiments, instead dicing one or both wafers 100, 110, the wafers may be used as a whole. For example, the wafers 100, 110 may be formed and bonded together to form a single large CBA memory wafer. Thereafter, multiple processors 175 may be bonded on top of the CBA memory wafer.

### High Bandwidth Flash Stacks and Hybrid High Bandwidth Flash Stacks Providing High Capacity Low Latency Storage Memory for an Artificial Intelligence Processor

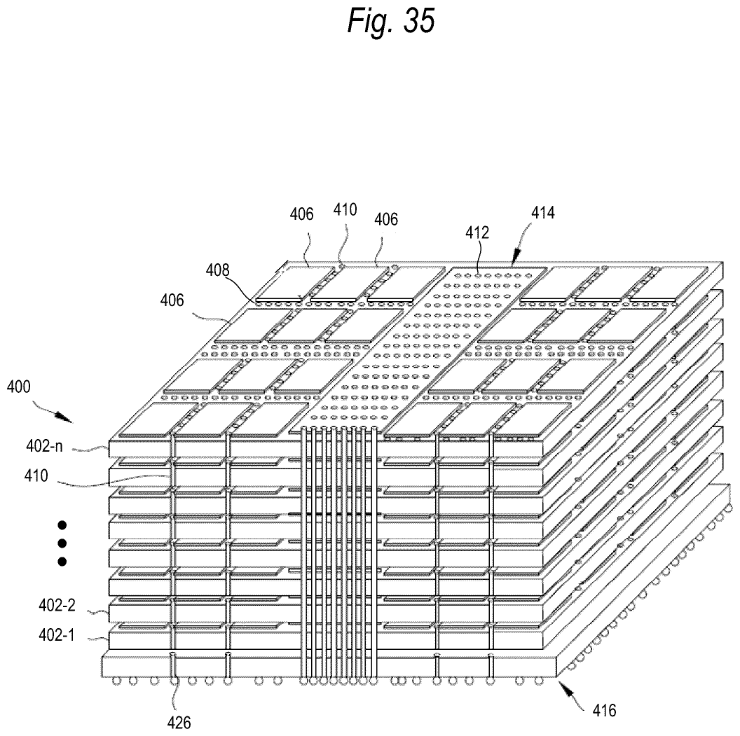

In embodiments described above, the processor 175 may be supported by HBM stacks 176 of DRAM memory. In a further aspect of the present technology, the processor 175 may instead be supported by stacks of non-volatile memory, referred to herein as high bandwidth flash (HBF) stacks, or stacks of memory including both volatile and non-volatile memory, referred to herein as hybrid HBF stacks. Details of these inventive aspects are described below with reference to FIGS. 35-40.

FIG. 35 is a perspective view of a single HBF stack 400. Each stack 400 may include a number of semiconductor dies 402, indicated in FIG. 35 as dies 402-1, 402-2, . . . , 402-n. In one example, there may be eight semiconductor dies 402 in the stack 400, but there may be other numbers of semiconductor dies including for example 1, 2, 4, 16, 32 and 64 dies. Each of the semiconductor dies 402 in an HBF stack may be a non-volatile memory such as NAND. The NAND dies 402 may be formed from a single wafer, or the NAND dies may be formed from a memory cell array wafer together with a CMOS logic circuit wafer to form CMOS bonded array (CBA) memory dies. Such dies may be analogous to the CBA memory tiles 160 described above, but may be smaller. Other types of non-volatile memory are possible, including MRAM.

Each of the dies may be subdivided into storage structures 406, also referred to herein as planes 406. Each plane 406 on a given semiconductor die 402 may be aligned with a corresponding plane 406 in the other semiconductor dies 402 in stack 176. In one example, each die 402 may include 24 planes 406, but there may be more or less planes 406 in further embodiments, including for example 36 planes and 64 planes.

In an example, each plane 406 on each die 402 may be accessed independently and in parallel with each other plane 406 on each die 402. To accomplish this, each plane 406 has its own set of dedicated signal lines. Each of these signal lines is defined by one of the TSVs 408, 410 and 412. The TSVs 408 may extend in rows adjacent each plane 406. The TSVs 410 may extend in columns adjacent each plane 406. Each semiconductor die 402 may further a TSV channel 414 that includes the TSVs 412. In an example, the TSV channel 414 is provided in middle portion of the semiconductor dies 402, aligned along the columns and/or rows of the planes 406. In an example, the TSV channel 414 includes one thousand twenty-four TSVs 412. However, the number of TSVs 412 in channel 414 may be higher or lower than this in further embodiments. While channel 414 is shown as including a grid of TSVs 412, other patterns are possible. The TSVs 408, 410 and 412 extend through each semiconductor die 402 in stack 400, and they are coupled to a controller die 416 at the bottom of the stack. Within a given plane 406, the TSVs 408, 410 and 412 are coupled to the individual memory arrays by metallization layers, not shown in FIG. 35 but described above.

A set of TSVs 408, 410 and/or 412 may be coupled to the memory arrays of each plane 406. Because each plane 406 is associated with its own set of signal lines, data may be directly written to, and/or directly read from, each plane 406 independently and in parallel with each other plane 406. In an example, each set of signal lines may include eight-bit I/O lines comprising eight separate signal lines. Although eight signal lines are shown and described, each set of signal lines may have any number of signal lines. For example, each set of signal lines can support up to two hundred fifty-six (or more) lines/signals. As a result, a wide-word high bandwidth is achieved by signal connections within the HBF stack 400.

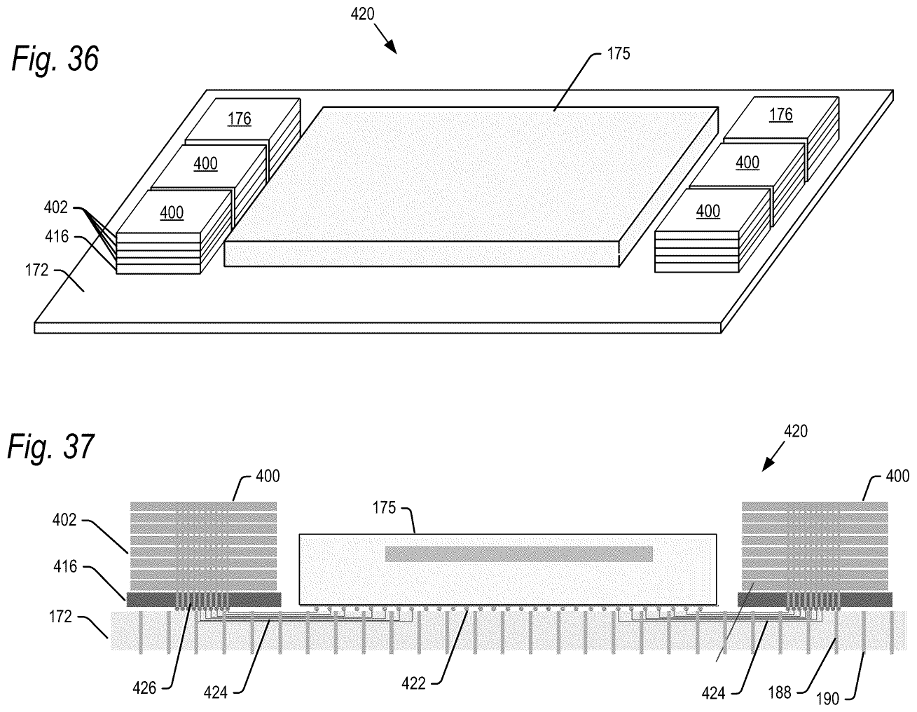

FIG. 36 is a perspective view of a completed processing core 420 including a processor 175 mounted directly on an interposer 172, and surrounded by stacks of memory including both HBM stacks 176 (of volatile memory) and HBF stacks 400 (of non-volatile memory). FIG. 37 is a cross-sectional view through the processing core 420 and through the HBF stacks 400. FIG. 37 for example shows bump pads 422 between the processor 175 and the interposer 172 to electrically and physically couple the processor 175 directly to the interposer 172. Electrical traces 424 are further shown within layers of the interposer 172 for electrically coupling the processor 175 to the HBF stacks 400. A bottom surface of HBF stacks 400 may include micro-bump pads 426 for physically and electrically coupling the HBF stacks 400 to the interposer 172. Also shown are vias 186 through the interposer 172 coupled to pads or bumps 190 on a bottom surface of the interposer 172 for electrically coupling the processing core 420 to a printed circuit board of a host device (not shown).

Processing core 420 may for example be an AI processing core. During the inference phase where AI processing core 420 provides query responses, a high volume of read operations are performed requiring a large amount of memory. This memory need is satisfied by the HBF stacks 400. In formulating responses to queries, the processor 175 performs intermediate calculations that get written to memory. These write operations may be made to the HBM stacks 176, thus avoiding degradation of the HBF stacks 400 over time. While FIG. 36 shows two HBM stacks 176 and four HBF stacks 400, these numbers may vary relative to each other depending on the needs of processor 175. As also noted, additional HBM and/or HBF stacks 176, 400 may be provided around additional sides of the processor 175.

Traditionally, stacks of non-volatile memory have not been used to support a specialized processor such as processor 175 as non-volatile memories have high latencies and are not fast enough. However, features of the present technology allow the HBF stacks 400 to be formed entirely of non-volatile memories. This greatly increases the storage capacity available to processor 175, while at the same time meeting the bandwidth and low latency requirements of processor 175.

One reason the stacks 400 may be formed entirely of non-volatile memory dies and still meet the high bandwidth requirements of the specialized processor 175 is parallelism of data operations that occur within the stacks 400. As noted above, each stack may be formed planes 406 (FIG. 35). Each of these planes 400 may be accessed individually accessed in parallel. This greatly increases the speed with which data may be accessed from the HBF stacks 400.

Another reason the stacks 400 may be formed entirely of non-volatile memory dies and still meet the high bandwidth requirements of the specialized processor 175 is the wide-word signal channel used in HBF stacks 400. As described above, each set of signal lines may include eight-bit I/O lines comprising eight separate signal lines. There may be up to two hundred fifty-six (or more) lines/signals in further embodiments. This results in a low latency, high bandwidth exchange of data between the HBF stacks 400 on interposer 172 and the processor 175.

A further reason the stack 176 may be formed entirely of non-volatile memory dies and still meet the high bandwidth requirements of the specialized processor 175 is the nature of AI and other specialized processors. Processors such as AI processors are able to prefetch data from the HBF stacks 400. In particular, while AI processor 155 is able to perform steps and computations in nanoseconds, traditionally it can take microseconds (1000 times slower) for a NAND memory to locate and access the requested data from its memory. This can result in high latency in processor 175 processing information.

However, when a processor 175 according to the present technology receives a query for example comprised of a number of tokens, the processor will have the microsecond delay in processing the first token. However, when sending a request for data for the first token, the processor may also send a request for data for the second and subsequent tokens to the HBF stack 400. Thus, the controller 416 of the HBF stack 400 can prefetch data associated with the second and subsequent tokens. This prefetched data can be stored in a buffer within controller 416 or elsewhere conveniently accessible to the processor 175. When the processor has completed its processing and computations on the first token, and a data request is sent for the second and subsequent tokens, the prefetched data for the second and subsequent tokens is sent. There is no need to wait the microseconds it would otherwise take (without prefetching) to access the data for each of the second and subsequent tokens from memory. This again greatly reduces latency with which data can be accessed from the HBF stacks 400.

These features enable the HBM stack(s) 176 as high capacity, high bandwidth non-volatile memory devices to support processor 175. For example, an HBF stack 400 formed of all non-volatile memory may have two TBs or more of storage capacity, which is significantly higher than current HBMs formed of volatile memory. At the same time, an HBF stack 400 formed of all non-volatile memory may have bandwidth capabilities of at least 1.5 TBs per second, which is sufficient to meet the bandwidth needs of processor 175. The storage capacity and bandwidth provided above are by way of example, and may be higher or lower in further embodiments.

As noted, it is useful to provide both HBF and HBM stacks around a specialized processor 175 so that the HBF stacks can be used to support high storage capacity read operations and the HBM stacks can be used to support the processor intermediate write operations without degrading the memory. In a further aspect of the present technology, the HBF and HBM stacks may be integrated together to form hybrid HBF stacks having both volatile memory and non-volatile memory.

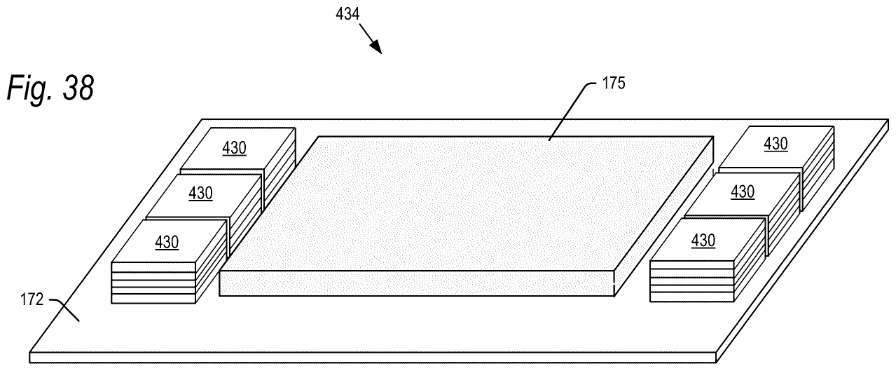

Examples of such hybrid HBF stacks 430 as shown in the perspective view of FIG. 38. Each hybrid stack 430 may be fabricated and assembled in the same way as HBF stacks 400, and to have the same planes and TSVs as HBF stacks 400. However, hybrid HBF stacks 430 contain a mix of both volatile memory dies such as DRAM and non-volatile memory dies such as NAND.

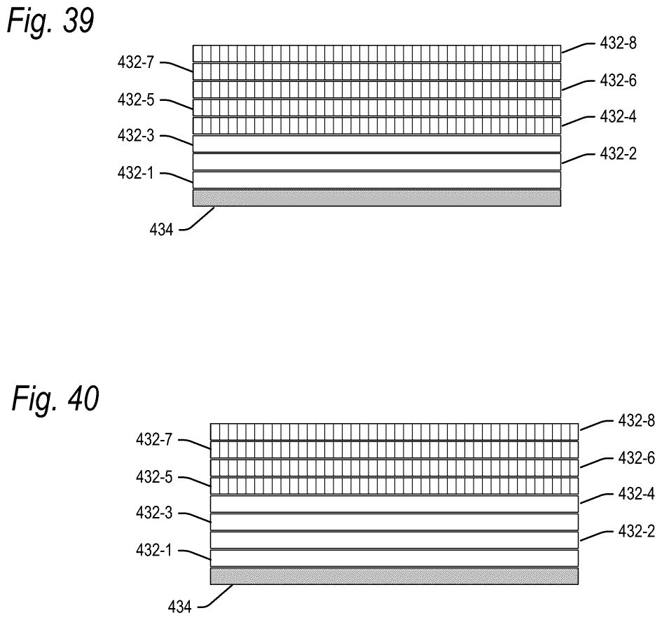

The edge view of FIG. 39 shows one possible configuration of the dies 432 within hybrid HBF stack 430. In one example, some of the dies 432 (i.e., dies 432-1, 432-2 and 432-3) may be volatile memory dies, and the remaining dies 432 (i.e., dies 432-4, 432-5, 402-6, 432-7 and 432-8) may be non-volatile memory dies. The controller 434 is configured with circuits and protocols that are specific to each memory type so that the single controller 434 is able to manage all of the dies in the hybrid HBF stack 430. In further embodiments, both the volatile memory dies and the non-volatile memory dies may be designed to follow the same protocols. The edge view of FIG. 40 shows one possible other configuration, where half the dies 432 (i.e., dies 432-1, 432-2, 432-3 and 432-4) may be volatile memory dies, and the remaining dies 432 (i.e., dies 432-5, 402-6, 432-7 and 432-8) may be non-volatile memory dies. In embodiments, the volatile dies may be nearer the bottom of the stack.

The hybrid stacks 430 may be used with a processor 175 as shown in FIG. 38 to provide a processing unit 434. When read operations are performed by the processor 175, the processor may access one or more of the non-volatile memories in one or more of the hybrid HBF stacks. When write operations are performed by the processor 175, the processor may access one or more of the volatile memories in one or more of the hybrid HBF stacks. It is understood that any combination of volatile and non-volatile memory dies may be used in a stack 430, depending on the storage capacity needs and access speed needs of the processor 175. In embodiments, each hybrid HBF stack 430 has the same composition of volatile and non-volatile memories. However, it is possible that two or more stacks 430 may have different composition of volatile and non-volatile memories in further embodiments.

In summary, an example of the present technology relates to a semiconductor device, comprising: a signal carrying medium; a processing core mounted on the signal carrying medium; and one or more stacks of high bandwidth flash (HBF) memory mounted on the signal carrying medium, each stack of HBF memory comprising: a plurality of non-volatile memory dies, and a controller die; wherein each stack of HBF memory is electrically coupled to the processing core to provide high bandwidth memory support to the processing core.

In a further example, the present technology relates to a semiconductor device, comprising: a signal carrying medium; a processing core mounted on the signal carrying medium; one or more stacks of hybrid high bandwidth flash (HBF) memory mounted on the signal carrying medium, each stack of hybrid HBF memory comprising: a plurality of non-volatile memory dies, a plurality of volatile memory dies, and a controller die controlling I/O operations to the plurality of non-volatile memory dies in the stack and controlling I/O operations to the plurality of volatile memory dies in the stack; wherein each stack of hybrid HBF memory is electrically coupled to the processing core to provide high bandwidth memory support to the processing core.

In another example, the present technology relates to a semiconductor device, comprising: a signal carrying medium; a processing core mounted on the signal carrying medium; and non-volatile flash memory means, mounted on the signal carrying medium adjacent to the processing core and electrically coupled to the processing core, for providing at least 1.5 terabytes per second bandwidth support to the processing core, and providing at least 2 terabytes of storage capacity support to the processing core.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor device, comprising:
a signal carrying medium;
a processing core mounted on the signal carrying medium; and
one or more stacks of high bandwidth flash (HBF) memory mounted on the signal carrying medium, each stack of HBF memory comprising:
a plurality of non-volatile memory dies, and
a controller die;
wherein each stack of HBF memory is electrically coupled to the processing core to provide high bandwidth memory support to the processing core.

2. The semiconductor device of claim 1, wherein the plurality of non-volatile memory dies in a stack of the one or more stacks of high bandwidth flash memory comprise NAND memory dies.

3. The semiconductor device of claim 1, wherein the plurality of non-volatile memory dies in a stack of the one or more stacks of high bandwidth flash memory comprise CBA memory dies, each CBA memory die comprising a NAND die coupled to a CMOS logic circuit die.

4. The semiconductor device of claim 1, wherein a stack of the one or more stacks of HBF memory comprise two or more non-volatile memory dies.

5. The semiconductor device of claim 1, wherein the one or more stacks of HBF memory comprise a plurality of stacks of HBF memory adjacent to and surrounding the processing core.

6. The semiconductor device of claim 5, further comprising one or more stacks of high bandwidth memory (HBM), each stack of the one or more stacks of HBM comprising a plurality of volatile memory dies.

7. The semiconductor device of claim 6, wherein the one or more stacks of HBM comprise a plurality of stacks of HBM adjacent to and surrounding the processing core.

8. The semiconductor device of claim 1, wherein each non-volatile memory die in a stack of HBF memory comprises a plurality of planes.

9. The semiconductor device of claim 8, wherein the stack of HBF memory further comprises a plurality of signal lines, each plane of the stack of HBF memory having its own set of dedicated signal lines of the plurality of signal lines.

10. The semiconductor device of claim 9, wherein the controller is configured to access the plurality of the planes in the non-volatile memory die independently and in parallel via the plurality of signal lines.

11. The semiconductor device of claim 9, wherein the set of dedicated signal lines for each plane comprise between eight-bit I/O signal lines and two hundred and fifty-six bit I/O signal lines.

12. The semiconductor device of claim 1, wherein the processing core is an artificial intelligence (AI) processing core.

13. The semiconductor device of claim 12, further comprising volatile memory electrically coupled to the AI processing core, wherein write operations performed by the AI memory core are written to the volatile memory, and read operations performed by the AI memory core are read from the one or more stacks of HBF.

14. The semiconductor device of claim 12, wherein the AI processing core prefetches data from the one or more stacks of HBF memory.

15. The semiconductor device of claim 1, wherein a stack of the one or more stacks of HBF memory provides at least two terabytes of storage capacity and provides bandwidth capabilities of at least 1.5 terabytes per second.

16. A semiconductor device, comprising:
a signal carrying medium;
a processing core mounted on the signal carrying medium;
one or more stacks of hybrid high bandwidth flash (HBF) memory mounted on the signal carrying medium, each stack of hybrid HBF memory comprising:
a plurality of non-volatile memory dies,
a plurality of volatile memory dies, and
a controller die controlling I/O operations to the plurality of non-volatile memory dies in the stack and controlling I/O operations to the plurality of volatile memory dies in the stack;
wherein each stack of hybrid HBF memory is electrically coupled to the processing core to provide high bandwidth memory support to the processing core.

17. The semiconductor device of claim 16, wherein the one or more stacks of hybrid HBF memory comprise a plurality of stacks of hybrid HBF memory adjacent to and surrounding the processing core.

18. The semiconductor device of claim 16, wherein the processing core is an artificial intelligence (AI) processing core.

19. The semiconductor device of claim 18, wherein write operations performed by the AI memory core are written to the volatile memory dies within a stack of the one or more stacks of hybrid HBF, and read operations performed by the AI memory core are read from the non-volatile memory dies within the stack.

20. A semiconductor device, comprising:
a signal carrying medium;
a processing core mounted on the signal carrying medium; and
memory means, mounted on the signal carrying medium adjacent to the processing core and electrically coupled to the processing core and comprising at least one or more non-volatile memory dies, for providing at least 0.5 terabytes per second bandwidth support to the processing core, and providing at least 256 gigabytes of storage capacity support to the processing core.
